(19) United States
(12) Patent Application Publication
(10) Pub. No.: US 2017/0026206 A1
(43) Pub. Date: Jan. 26, 2017

(54) SYSTEM AND METHOD FOR PREVENTING PHANTOM DATA COMMUNICATION LINKS

(71) Applicant: Ikanos Communications, Inc., Fremont, CA (US)

(72) Inventors: Hubert De Lassus, New York, NY (US); Ashok Baragi Baragi Nagappa, Bangalore (IN); Vishveshwara Chaya Ramanna, Bangalore (IN); Karthik Muralidhar, Bangalore (IN)

(21) Appl. No.: 15/283,892

(22) Filed: Oct. 3, 2016

Related U.S. Application Data
(63) Continuation-in-part of application No. 14/983,104, filed on Dec. 29, 2015.
(60) Provisional application No. 62/097,969, filed on Dec. 30, 2014.

(51) Int. Cl. H04L 25/08; H04L 12/26

(52) U.S. Cl. CPC H04L 25/08; H04L 43/16; H04L 2012/6478

(57) ABSTRACT

A method and a system for preventing phantom data communication links from occurring that substantially eliminates or reduces at least some of the disadvantages and problems associated with previous data communication network management techniques. In accordance with a particular embodiment of the present disclosure a method for managing data communications is provided that comprises the step of providing a central office data communication switch that comprises a plurality of data communication ports. A port controller causes the ports to estimate various physical characteristics of the incoming signals from network termination points. This processing of incoming signals leads to the precise detection of phantom links and their immediate termination. Thus, this method prevents the formation of phantom links that may occur if physical conductors which are susceptible to crosstalk interference with connected conductors erroneously convey a response signal back to an unattached port within the head-in switching system.

### CROSS REFERENCES

The present application for patent in a continuation-in-part of U.S. patent application Ser. No. 14/983,104 by DeLassus, entitled “System and Method for Preventing Phantom Data Communication Links,” filed Dec. 29, 2015 which claims priority to U.S. Provisional Patent Application No. 62/097,969 by De Lassus, entitled “System and Method for Preventing Phantom Data Communication Links,” filed Dec. 30, 2014, assigned to the assignee hereof, and expressly incorporated by reference herein.

### FIELD OF THE DISCLOSURE

The present disclosure relates generally to data communications, and more particularly to a system and method for preventing phantom data communication links and to training of transceivers in a xDSL communications system.

### DESCRIPTION OF RELATED ART

The rapid growth of the internet and the content available through the internet has increased the demand for high bandwidth connectivity. Digital subscriber line (DSL or xDSL) technology meets this demand by providing data service over existing twisted pair telephone lines. DSL can be deployed from central offices (COs), from fiber-fed cabinets preferably located near the customer premises, or within buildings. DSL technology achieves higher data transmission rates by taking advantages of unused frequencies, which are significantly higher than voice band frequencies, on the existing twisted pair lines. While current generations of DSL such as VDSL2 extend between 1 and 30 MHz in frequency, the newer generations of DSL systems such as G.FAST lines utilize very high frequency transmission on the order of 1 to 200 MHz in frequency or higher.

DSL systems typically include multiple bundles of twisted pair wires that may be located within close proximity to each other. Because of the high frequencies involved, communication occurring on one wire may degrade or substantially disrupt communication on an adjacent wire by causing electromagnetically induced crosstalk on the adjacent wire. These crosstalk or phantom data link signals on neighboring wires can severely disrupt communications on the impacted wires. In addition, if the proximate wires are not being used at the particular time, the systems connected to those wires may erroneously conclude that data communications are being attempted from a device connected to the wires. If these induced signals are not eliminated or disregarded, they can result in systems assuming that a data communication link has occurred on the unused wire. This condition is referred to as phantom link and can result in serious disruption to the management of the data communication network.

### SUMMARY

The present description provides a method and a system for preventing phantom data communication links from occurring that substantially eliminates or reduces at least some of the disadvantages and problems associated with previous data communication network management techniques. In accordance with a particular embodiment of the present disclosure, a method for managing data communications is provided that includes the step of providing a central office data communication switch having multiple data communication ports. A phantom link detector estimates or measures various physical characteristics of the incoming signals from network termination points associated with the data communication ports. This processing of incoming signals leads to the precise detection of phantom links and their immediate termination. Thus, this method prevents the formation of phantom links that may occur if physical conductors which are susceptible to crosstalk interference with connected conductors erroneously convey a response signal back to an unattached port within the head-in switching system.

A method of wireless communication is described. The method may include receiving, by a central office (CO) device, a transmission from a customer premises equipment (CPE) device comprising a request for a new DSL connection over a first set of tones in a first uplink band and a second set of tones in a second uplink band outside of the first uplink band, measuring, by the CO device, a signal energy of the received request to obtain a frequency response of the received request over the first band and the second band, and detecting a phantom data communication link based at least in part on a slope of the frequency response of the received request over the first band and the second band.

An apparatus for wireless communication is described. The apparatus may include means for receiving, by a central office (CO) device, a transmission from a customer premises equipment (CPE) device comprising a request for a new DSL connection over a first set of tones in a first uplink band and a second set of tones in a second uplink band outside of the first uplink band, means for measuring, by the CO device, a signal energy of the received request to obtain a frequency response of the received request over the first band and the second band, and means for detecting a phantom data communication link based at least in part on a slope of the frequency response of the received request over the first band and the second band.

A further apparatus is described. The apparatus may include a processor, memory in electronic communication with the processor, and instructions stored in the memory. The instructions may be operable to cause the processor to receive, by a central office (CO) device, a transmission from a customer premises equipment (CPE) device comprising a request for a new DSL connection over a first set of tones in a first uplink band and a second set of tones in a second uplink band outside of the first uplink band, measure, by the CO device, a signal energy of the received request to obtain a frequency response of the received request over the first band and the second band, and detect a phantom data communication link based at least in part on a slope of the frequency response of the received request over the first band and the second band.

A non-transitory computer readable medium for wireless communication is described. The non-transitory computer-readable medium may include instructions to cause a processor to receive, by a central office (CO) device, a transmission from a customer premises equipment (CPE) device comprising a request for a new DSL connection over a first set of tones in a first uplink band and a second set of tones in a second uplink band outside of the first uplink band, measure, by the CO device, a signal energy of the received request to obtain a frequency response of the received request over the first band and the second band, and detect a phantom data communication link based at least in part on a slope of the frequency response of the received request over the first band and the second band.

In some examples of the method, apparatus, or computer readable medium described above, a time average of the transmission from the CPE device is determined, and the slope of the frequency response is determined based at least in part on the time average. The phantom data communication link may be detected based at least in part on a difference between the slop of the frequency response and a threshold. In some cases, determining the slope of the frequency response utilizes a least squares fit method.

In some examples of the method, apparatus, or computer readable medium described above, detecting the phantom data communication link includes measuring a signal energy of the received request and comparing the measured signal energy against a predetermined threshold.

In some examples of the method, apparatus, or computer readable medium described above, the first uplink band comprises at least one of: an ITU U0 band, an ITU U1 band, or both. The first set of tones may comprise at least one of: an ITU G.994 A43 tone set or an ITU G.994 V43 tone set.

In some examples of the method, apparatus, or computer readable medium described above, the received request is a modified R_TONES_REQ signal, and the modified R_TONES_REQ signal includes a plurality of tones spaced evenly over the second uplink band. The second uplink band may include at least one of: an ITU U2 band, an ITU U3 band, or both.

In some examples of the method, apparatus, or computer readable medium described above, a downlink band is between the first uplink band and the second uplink band.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purpose of illustration and description only, and not as a definition of the limits of the claims.

### BRIEF DESCRIPTION OF THE DRAWINGS

A further understanding of the nature and advantages of the present disclosure may be realized by reference to the following drawings. In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 is an example of a network configuration, which may be configured for communicating data, with CPEs communicatively coupled to a CO via a cable bundle.

FIG. 2 illustrates an example of a network subsystem which may be configured for communicating data, with CPEs communicatively coupled to a CO via a cable bundle.

FIGS. 3A and 3B show block diagrams of COs configured to detect phantom links in accordance with various aspects of the present disclosure.

FIGS. 4 and 5 are flow charts illustrating example methods for detecting phantom links in accordance with various aspects of the present disclosure.

FIG. 6 illustrates two scenarios of CPE to CO upstream communication.

FIG. 7 illustrates a graph of the log of attenuation vs. frequency of a direct-link signal and phantom data link signal in a physically connected line.

FIG. 8 illustrates timing diagrams of the output of a low pass filter.

FIG. 9 illustrates a scenario of CO to CPE downstream communication.

FIG. 10 is a flow chart illustrating example methods for detecting phantom links in accordance with various aspects of the present disclosure.

### DETAILED DESCRIPTION

The present disclosure provides a method and a system for preventing phantom data communication links from occurring that substantially eliminates or reduces at least some of the disadvantages and problems associated with previous data communication network management techniques.

In accordance with a particular embodiment of the present disclosure, a method and system for managing data communications is provided that comprises a central office data communication port controller that comprises a plurality of data communication ports. A phantom link detector is communicatively coupled to the ports and is configured to measure various twisted pair signal characteristics. Twisted pair signal characteristics include attenuation, delay skew, propagation delay, phase shift, return loss, near end cross talk, and far end cross talk. A feature vector can include any combination of these characteristic values or values extracted from these original characteristics by way of mathematical transformation, or projection. These measured parameters are then utilized to determine if a phantom link exists on the tested line.

An example method occurs during training where physical characteristics of an incoming signal are measured and then these characteristics are compared to expected values using the framework of a phantom link detector. These measurements may be taken during the handshake or discovery procedures of training. If the comparison does not match, the incoming signal is labeled as phantom link and the port is aborted. The comparison may be made in terms of either a static or adaptive threshold.

Another example method according to another embodiment of the disclosure measures the physical characteristics of an incoming signal. These measurements may be taken during the handshake or discovery procedures of training. These physical measurements are then utilized to calculate estimated values of physical attributes of the data communications line under test. If the estimated values do not roughly match, the incoming signal is labeled as phantom link and the port is aborted. The comparison may be made in terms of either a static or adaptive threshold.

In another exemplary embodiment, steps may be taken to adapt methods found in the current disclosure to variations in the line under test. For example, indications of bridge taps on the line could affect the calculations utilized in the aforementioned methods. Bridge taps can be more prevalent in some regions than others, and algorithms may be adjusted based on where the line is being analyzed. The presence of bridge taps can also be found through manual testing of the lines or through records detailing the location of bridge taps.

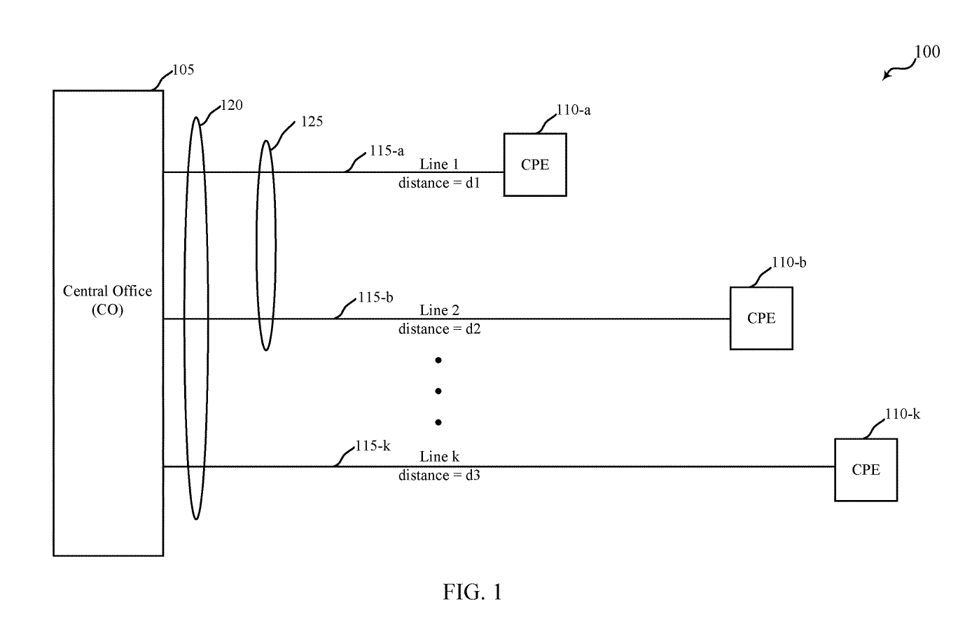

FIG. 1 illustrates an example of a network configuration 100. The configuration comprises a Central Office (CO) 105 that is connected to a number of remote nodes, such as Consumer-premises equipment (CPEs) 110, via a cable bundle 120 comprising one or more sub-bundles 125. The CPEs 110 are communicatively coupled to the CO 105 via respective subscriber lines denoted 115-a, 115-b, through to 115-k. Each of the lines 115-a, 115-b, 115-k include, for example, one or more twisted-pair copper wire connections. The CPEs 110 are located at various distances (d1, d2, d3) from the CO. A given CPE 110 may comprise, by way of example, a modem, a computing device, or other types of communication devices, or combinations of such devices which are configured to receive data from a CO 105.

Communications between the CO 105 and the CPEs 110 include both downstream and upstream communications for each of the active lines. The downstream direction refers to the direction from CO 105 to CPE 110, and the upstream direction is the direction from CPE 110 to CO 105. Although not explicitly shown in FIG. 1, each of the subscriber lines 115 of network configuration 100 includes a CO transmitter and a CPE receiver for use in communicating in the downstream direction, and a CPE transmitter and a CO receiver for use in communicating in the upstream direction. On both the CO 105 and CPE 110 side, hardware implementing both a transmitter and a receiver is generically referred to as a modem.

Because different lines 115 are in close proximity with each other in cable bundles 120 and sub-bundles 125, these lines 115 can be susceptible to crosstalk interference. Hence, data signals transmitted on neighboring or close-proximity lines 115 can be superimposed on and contaminate each other. Based at least in part on such crosstalk, data signals transmitted over the lines 115 can be considerably degraded by the crosstalk interference generated on one or more adjacent lines 115 in the same and/or a nearby multi-core cable or cable bundle 120. Accordingly, a transmission on one subscriber line 115 may be detected on other subscriber lines 115.

To help ameliorate the issue of transmitting and receiving data on a line that has been compromised by crosstalk interference, CO 105 incorporates a plethora of methods to identify phantom links among one or more data communications lines. One method involves CO 105 receiving a signal from a line 115 under test. From this signal, CO 105 measures at least two parameters of the signal from a variety of signal parameters including attenuation, delay skew, propagation delay, phase shift, return loss, near end cross talk, and far end cross talk. In one embodiment, CO 105 takes a first and second measured parameter and determines an expected value of the second parameter based at least in part on the measurement of the first parameter of the signal. From these derived values, CO 105 can detect a phantom data communication link based at least in part on a difference between the expected value of the second parameter of the signal and the measurement of the second parameter of the signal. In some instances, the two parameters are linked such that there is a unique mapping between them. Therefore, if one parameter is measured from the signal another distinct parameter may be estimated from that measured parameter.

In another embodiment, CO 105 can take the at least two measured parameters of the received signal and utilize them separately to compute two different estimates of a physical attribute of a data communications line. One example of a physical attribute of a data communications line that can be derived from the measured parameters is the loop length of the line. Utilizing the two different estimates of the physical attribute, CO 105 can then detect a phantom data communication link based at least in part on a difference between the first estimate and the second estimate.

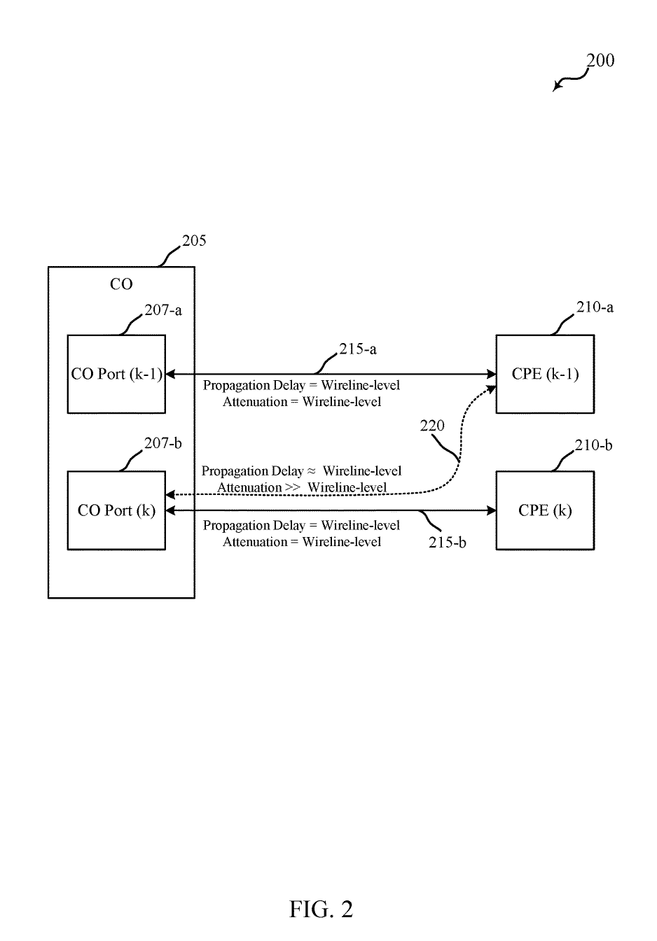

FIG. 2 shows another example of a network configuration 200. CO port 207-a of CO 205 is communicatively coupled to CPE 210-a via a first data communications line 215-a, such as a twisted copper wire pair. Similarly, CO port 207-b is communicatively coupled to CPE 210-b via a second data communications line 215-b, such as a twisted copper wire pair. When the first data communications line 215-a between CO port 207-a and CPE 210-a is under test, a signal is propagated from CO port 207-a to CPE 210-a and then the signal loops back to CO port 207-a from CPE 210-a. When the signal is initially propagated, the CO 205 knows certain initial parameters about the signal such as the initial signal power and an indication of time that the signal was transmitted. The initial signal power can be standardized, and the time that the signal was transmitted may be recorded using one or more time stamps. When a signal is subsequently received by CO port 207-a from CPE 210-a, the associated CO can determine certain parameters from the received signal such as the attenuation and propagation delay of the first data communications line 215-a. The same calculations can be done on the second data communications line 215-b when CO port 207-b performs a line test with CPE 210-b.

In a particular example where the first data communications line 215-a and second data communications line 215-b are coupled together in cable bundles such as cable bundle 120 and sub-bundle 125, communication occurring on the first data communications line 215-a may degrade or substantially disrupt communication on the second data communications line 215-b by causing electromagnetically induced crosstalk. In a scenario where appropriate crosstalk or phantom link mitigation is not undertaken, a situation may occur where the CO 205 may try to perform a handshake or discovery procedure with CPE 210-b, but due to crosstalk the CO 205 instead erroneously performs the procedure with CPE 210-a (also known as a phantom link 220).

The methods of the present disclosure provide means to identify these phantom links and to decline any connections on lines known to be phantom links. In one example, CO port 207-b may initiate a handshake procedure with CPE 210-b. At the outset the CO 205 knows the initial power and an indication of time of the propagated signal and from the received signal the CO 205 can calculate the attenuation and the propagation delay of the line through techniques known in the art. Because there is a unique, non-linear mapping between the attenuation and the propagation delay of the line, once the CO 205 determines one parameter from the received signal it can estimate the other. For example, if the received signal had a certain propagation delay the CO 205 could then estimate what the associated signal attenuation should be for that line. If the measured signal power is much less (e.g., >20 dB) than what the estimated attenuation should have been based on the measured propagation delay then it is likely that the line under test is a phantom link 220. This is largely due to the fact that the transmitted signal has migrated from one line to another and has been attenuated by the sheaths physically separating the two lines. Under aspects described in the disclosure, when the CO 205 identifies phantom link 220 it can decline the connection on the phantom link.

In another example, when a handshake or discovery procedure is undertaken between CO port 207-b and CPE 210-b and the associated CO 205 receives a signal from the line under test, it can determine the attenuation and the propagation delay from the received signal. The CO 205 can then use each of the measured parameters in separate equations to determine two different estimated loop lengths of the line under test. If the two estimated loop lengths are roughly equal then the CO 205 will know that the line under test is not a phantom link. However, if the two estimated loop lengths do not roughly equal each other then it is likely that the signal propagated through phantom link 220.

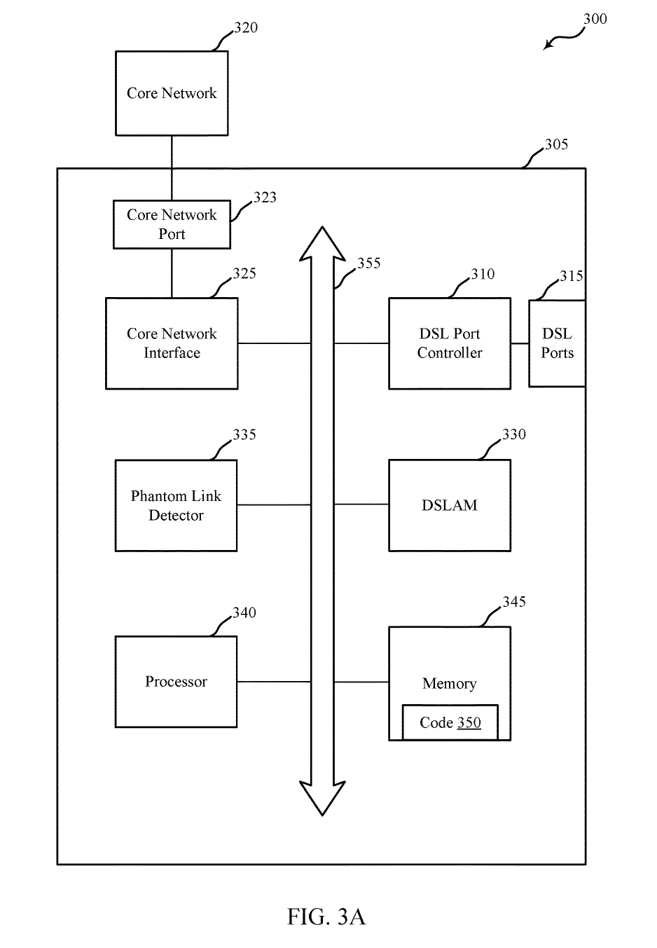

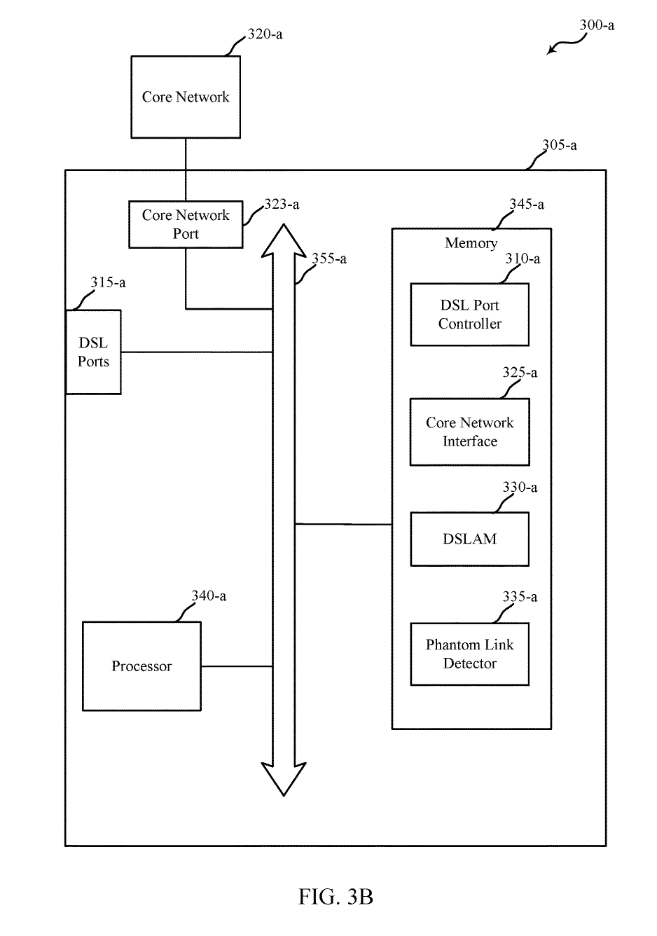

FIG. 3A shows a block diagram 300 of a CO apparatus 305 for use in detecting phantom links in accordance with various aspects of the present disclosure. The CO apparatus 305 may include a DSL port controller 310, one or more DSL ports 315, core network port 323, core network interface 325, digital subscriber line access multiplexer (DSLAM) 330, phantom link detector 335, processor 340, and a memory 345. Each of these components may be in communication with each other, directly or indirectly, over one or more buses 355.

The DSL port controller 310 is communicatively coupled to one or more DSL ports 315. DSL ports 315 are uniquely adapted to transmit and receive signals via twisted pair lines (such as the twisted pair lines 115-1 through 115-k of FIG. 2) or other wireline types and are communicatively coupled to CPEs 110. The DSL port controller 310 may send and receive controls and/or data from any of the other components over bus 355. DSL port controller may be a variety of transceiver devices including a modem.

Core network interface 325 communicates various data and controls with bus 355 and core network 320 via core network port 323. The core network 320 may provide access authorization, tracking, Internet Protocol (IP) connectivity, and other access, routing, or communications functions.

DSLAM 330 routes DSL connections established over DSL ports 315 to the Internet via the core network 320. DSLAM 330 combines a group of DSL connections associated with different lines and DSL ports 315 into one aggregate Internet connection. For example, DSLAM 330 may receive signals from all the CPEs in a certain neighborhood and patch them through to the Internet backbone. The DSLAM 330 processes each incoming connection and, in some cases, limits the bandwidth of certain DSL lines. Multiple DSLAMs 330 can be deployed to help route incoming and outgoing traffic in the most efficient way possible.

Phantom link detector 335 receives and processes all relevant information necessary to detect phantom links in accordance with various aspects of the present disclosure. Phantom link detector 335 may receive various measured parameters of one or more lines 115 and use the parameters to determine whether phantom links exist on the line being tested in accordance with the methods found in this disclosure. Phantom link detector 335 may take into account any adjustments, algorithms, and correction factors that may have a bearing on the determination of the existence of phantom links (e.g., bridge taps, timing advance, etc.). Phantom link detector 335 may make time average computations of various received signals, and then compute a slope of a magnitude response in the X43 tone set utilizing a least squares fit method and a mean squared error based at least in part on the computed time average. The phantom link detector 335 may receive a transmission from a customer premises equipment (CPE) device comprising a request for a new DSL connection over a first set of tones in a first uplink band and a second set of tones in a second uplink band outside of the first uplink band, measure a signal energy of the received request obtain a frequency response of the received request over the first band and the second band, and detect a phantom data communication link based at least in part on a slope of the frequency response of the received request over the first band and the second band. It may also measure a signal energy of a received signal and compare the measured signal energy against a predetermined threshold.

Processor 340 is an intelligent hardware device, e.g., a CPU, a microcontroller, an ASIC, etc. Processor 340 processes information received through the DSL port controller 310, core network interface 325, and/or DSLAM 330. Processor 340 may also process information to be transmitted via these blocks. Processor 340 may handle, alone or in connection with the phantom link detector 335, various aspects of phantom link detection.

Memory 345 may include random access memory (RAM) and/or read-only memory (ROM). Memory 345 may store computer-readable, computer-executable software/firmware code 350 containing instructions that are configured to, when executed, cause processor 340 to perform various functions described herein related to phantom link detection. Alternatively, the computer-readable, computer-executable software/firmware code 350 may not be directly executable by processor 340 but be configured to cause CO apparatus 305 (e.g., when compiled and executed) to perform various functions described herein.

In still other examples, the features of each component may also be implemented, in whole or in part, with instructions embodied in a memory, formatted to be executed by one or more general or application-specific processors. For example, FIG. 3B shows a block diagram 300-a of another example of a CO apparatus 305-a in which the features of the DSL port controller 310-a, the core network interface 325-a, DSLAM 330-a, and phantom link detector 335-a are implemented as computer-readable code stored on memory 345-a and executed by one or more processors 340-a. Other combinations of hardware/software may be used to perform the features of one or more of the components of FIGS. 3A-3B.

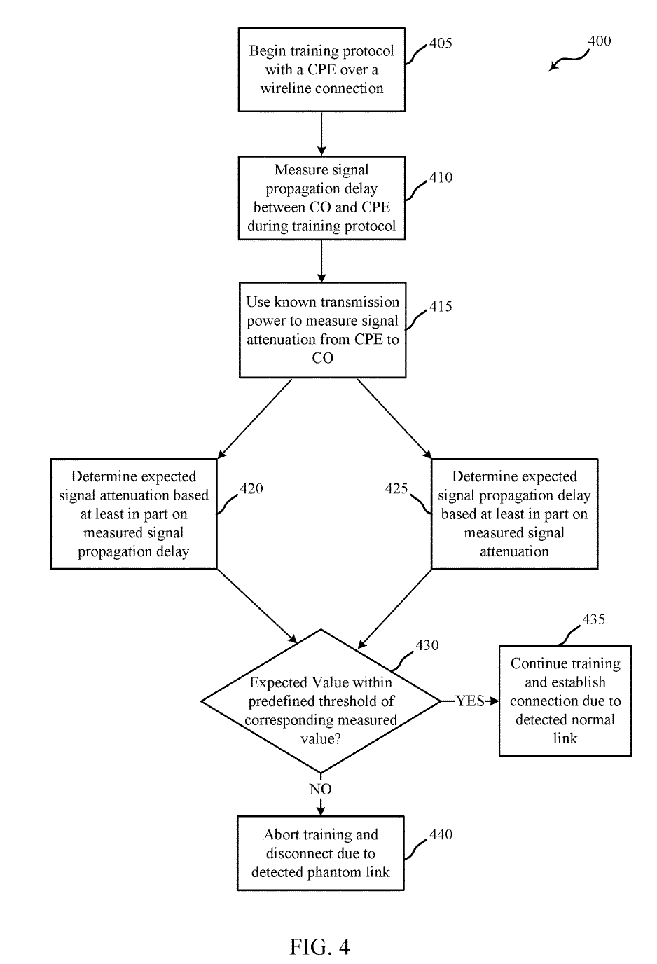

FIG. 4 is a flow chart illustrating an example of a method 400 for phantom link detection, in accordance with various aspects of the present disclosure. For the purposes of illustration, the method 400 will be described as it relates to the components of the CO apparatuses 305, 305-a shown in FIGS. 3A and 3B. This method 400 can also be performed by the COs 105, 205 shown in FIGS. 1-2, which may be examples of the CO apparatuses 305, 305-a shown in FIGS. 3A and 3B.

At block 405, the DSL port controller 310 of the CO apparatus 305 begins a training protocol with a designated CPE over a line associated with a DSL port 315. The DSL port controller 310 transmits a signal to the CPE over the DSL port 315 knowing certain initial parameters, such as the initial power of the signal and an indication of time at transmission. CPE then send a reply signal to the CO apparatus 305 over the DSL port 315. At block 410, CO apparatus 305 receives the signal from the CPE and measures the signal propagation delay between the CO apparatus 305 and the CPE using techniques known in the art.

Additionally in current DSL systems, the timing advance of the received signal in discovery can be used as a proxy for propagation delay after normalization by the sampling rate. In VDSL2 Vectoring (DSL Standard ITU G993.5), timing advance is a defined process for aligning the signals of different lines of one sheath or bundle of twisted pairs. In such a frequency division duplexing system, upstream and downstream symbols are multiplexed in frequency. To align the upstream symbols, the CO apparatus 305 tells each CPE how many time domain samples it must advance its upstream symbol transmission so that upstream symbols from all CPEs are received at the exact same time at the CO apparatus 305. Timing advance takes into account the various distances each CPE is from the CO apparatus 305. Therefore the timing advance expressed in time domain samples is a measure of the propagation delay of the signal of each line. For earlier versions of VDSL2 (DSL Standard ITU 993.2), also a frequency division duplexing system, timing advance is a method to align downstream and upstream symbols on a single line and is related to digital duplexing. This is also a measure of the signal propagation delay. For DSL Standard ITU G997.1 (G.FAST), the technology uses time division duplexing: upstream and downstream symbols are multiplexed in time. (Upstream and downstream signals alternate in time on the line.) In this case timing advance is called “time gap” and is used by the CO apparatus 305 to align in time the arrival of all upstream symbols of every line.

At block 415, DSL port controller 310 and phantom link detector 335 utilize the initial transmission power of the signal and determines the signal attenuation of the line under test. In a copper twisted pair signal propagation delay and attenuation, although independently measured, are commensurate and linked. In other words, there is a unique non-linear mapping between attenuation and propagation delay of a given line. These relationships can be attained via a lookup table, a neural network, a function generator, or any other suitable mathematical or computational tool.

Because there is a unique mapping between the two signal parameters, method 400 may then proceed in two different ways to determine if there is a phantom link on the tested line. Either of the two calculations are a valid means to detect a phantom link on the line. If the method proceeds to block 420, phantom link detector 335 utilizes the measured signal propagation delay to estimate a value of the signal attenuation of the tested line. If the method proceeds to block 425, phantom link detector 335 utilizes the measured signal attenuation to estimate a value of the propagation delay of the tested line.

After proceeding through either block 420 or 425, the method proceeds to block 430. At block 430 phantom link detector 335 compares the estimated value to its respective measured value from the received signal. The comparison that occurs determines whether the estimated value is within a certain predefined threshold from its corresponding measured value. In an illustrative example, in a case where a threshold is set at 20 dB, if the estimated signal attenuation and the measured attenuation differ by an amount greater than 20 dB then the signal is labeled as a phantom link. The threshold used may be a static threshold or an adaptive threshold that is changed periodically or aperiodically based on various circumstances such as physical conditions on the line being tested.

From block 430, if the expected value is within a predefined threshold of its corresponding measured value the method proceeds to block 435 where the DSL port controller 310 establishes a connection between the CO 105 and the CPE, and training is continued. If the expected value is not within a predefined threshold of its corresponding measured value, the method then proceeds to block 440 where no connection is established between the CO apparatus 305 and the CPE, and training is discontinued.

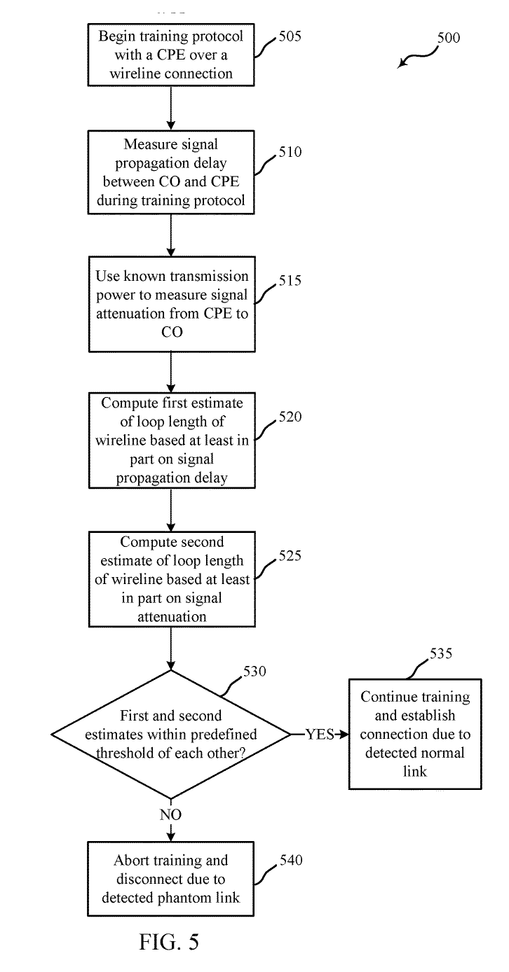

FIG. 5 is a flow chart illustrating an example of a method 500 for phantom link detection, in accordance with various aspects of the present disclosure. For the purposes of illustration, the method 500 will be described as it relates to the components of the CO apparatuses 305, 305-a shown in FIGS. 3A and 3B. This method 500 can also be performed by the COs 105, 205 shown in FIGS. 1-2, which may be examples of the CO apparatuses 305, 305-a shown in FIGS. 3A and 3B.

At block 505, the DSL port controller 310 of CO apparatus 305 begins a training protocol with a designated CPE over an associated line coupled to a DSL port 315. CO apparatus 305 transmits a signal to the CPE knowing certain initial parameters, such as the initial power of the signal and an indication of time at transmission. The CPE will then send a reply signal to CO apparatus 305. At block 510, CO apparatus 305 receives the signal from the CPE and measures the signal propagation delay between CO apparatus 305 and the CPE using techniques known in the art. The timing advance of the received signal can also be used as a proxy for propagation delay after normalization by the sampling rate as explained above.

At block 515, DSL port controller 310 utilizes the initial transmission power of the signal to determine the signal attenuation of the line under test. At blocks 515 and 520, phantom link detector 335 estimates a loop length of the line based at least in part on both the measured signal propagation delay and the signal attenuation acquired in blocks 510 and 515, respectively. For VDSL2 systems that transmit over normal polyethylene-insulated twisted pairs, an approximation L of the electrical length of the loop line can be computed by the following approaches:

$$L = \frac{1}{f} {\sum }_{f} \frac{A}{K * \sqrt{f}}$$

where K is a wire dependent constant, A is the attenuation in dB, and f the frequency; and

L=Delay*c*VOP, where Delay is the signal propagation delay normalized by the sampling rate, c is the speed of light, and VOP is the Velocity Of Propagation (a fraction between 1 and zero) characteristic of the wire dielectric material.

Other algorithms determining loop length utilizing different measured parameters of the signal may also be incorporated.

Once the estimated loop lengths are calculated in blocks 520 and 525, the method proceeds to decision block 530 where the phantom link detector 335 compares the estimated loop lengths. The difference between the two calculated loop lengths that would indicate the existence of a phantom link may be a static or adaptive threshold. If the two estimated lengths are within the predefined threshold of each other, the method proceeds to block 535 where DSL port controller 310 establishes a connection between CO apparatus 305 and the CPE, and training is continued. If the two estimated lengths are not within a predefined threshold of each other, the method then proceeds to block 540 where no connection is established between CO apparatus 305 and the CPE.

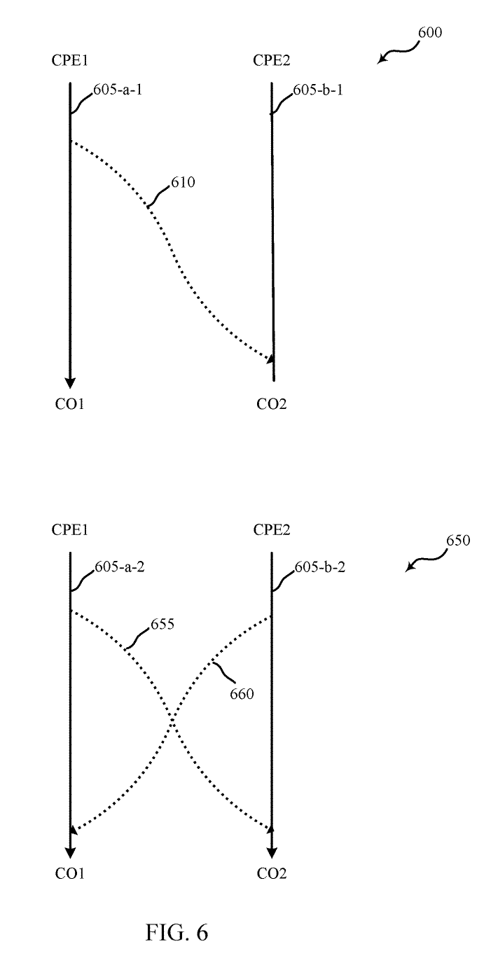

FIG. 6 depicts a first scenario 600 and a second scenario 650 (direct links are depicted with solid lines and phantom links are depicted with dashed lines). These scenarios can relate to the COs 105, 205 and CPEs 110, 210 shown in FIGS. 1-2. In the first scenario 600, CPE1 is switched ON, CPE2 is OFF, and there is a possibility of CO2 being connected to CPE1 via phantom link signal 610. In the second scenario 650, both CPE1 and CPE2 are switched ON within a small delay of each other, and there is a possibility of CO2 being connected to CPE1 via phantom link signal 655 and/or CO1 being connected to CPE2 via phantom link signal 660. Techniques described below may be utilized to detect phantom data communication links and mitigate the effects of phantom links between lines. These techniques may be performed during handshaking (e.g., G.hs) procedures between DSL transceivers.

In one technique for identifying a phantom link, the CO may distinguish the signal it receives as a direct-link signal or a phantom link signal by measuring the energy (or power) of the received signal. If the power is above a predetermined threshold, the CO may conclude that the received signal is a direct-link signal instead of a phantom link signal. If the power is below the threshold, the CO may determine that the received signal is a phantom link signal.

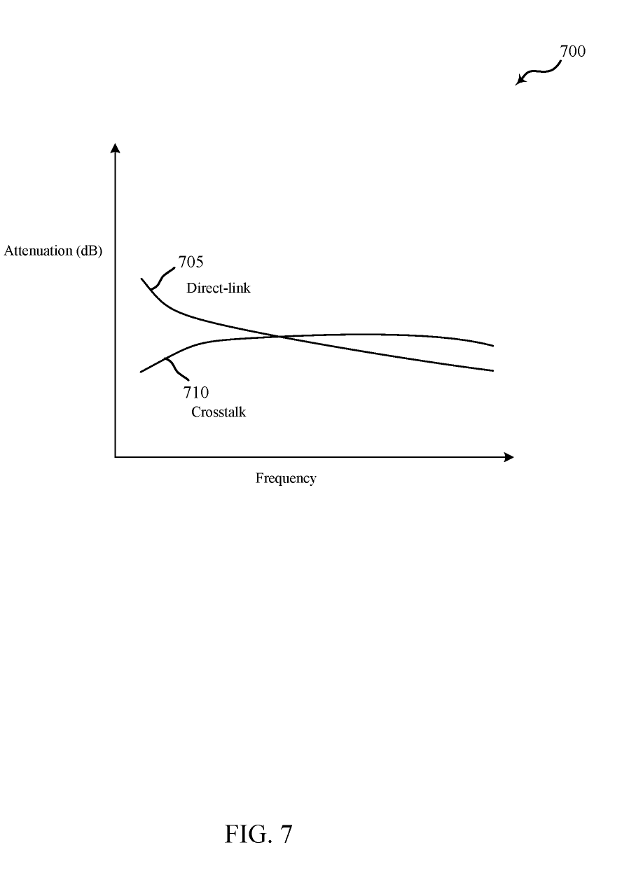

A second technique for identifying a phantom link utilizes the differences in the channel response between a direct-link signal and a phantom link signal. A direct-link signal may be characterized by an attenuation that increases with frequency while a phantom link signal may be characterized by an attenuation that decreases with respect to frequency. FIG. 7 illustrates a graph 700 of an example of channel responses for a direct-link signal 705 and phantom link signal 710 in a physically connected line. In this graph 700, the y-axis represents the log of signal attenuation and the x-axis represents frequency. This example may exhibit responses of CO1 and CO2 in scenario 600, where direct-link signal 705 depicts the channel response of CO1 and phantom link signal 710 depicts the channel response of CO2. As shown, the channel response for the direct-link signal 705 may be linear for most of the bandwidth of interest in the physically connected line. The slope of the direct-link signal 705 is negative, although the slope may depend in part on the properties of the physical cable used. The phantom link signal 710, however, does not exhibit this type of log-linear behavior. Similarly, the phase response is approximately linear for a direct-link signal on a physically connected line (within the bandwidth of interest and assuming bridge taps are compensated for). Phantom link signals do not show the same linear phase as direct-link signals.

The aforementioned channel responses may be utilized in determining phantom link signals. In this technique of identifying phantom link signals, the CPE may initiate a connection to a CO by transmitting a request for a new DSL connection. One example of such a request is a modified R-TONES-REQ signal. Standard R-TONES-REQ signals are defined in the ITU G.994.1 specification, and are transmitted over an A43 tone set and/or a V43 tone set of an ITU U0 and/or ITU U1 band. In this example, the R-TONES-REQ signal is modified to include an additional 6 tones in each of the ITU U2 and U3 bands, which may have a lower power spectral density than the A43 and V43 tone sets. (The tones used to transmit the modified R-TONES-REQ may be collectively referred to as an X43 tone set.) The additional 6 tones may be spaced evenly to cover each of the U2 and U3 bands. The R-TONES-REQ signal may be received by the CO via DSL port 315.

When the modified R-TONES-REQ signal is transmitted by the CPE, the CO may listen to the X43 tone set to measure a signal energy of the R-TONES-REQ signal and obtain a frequency response of the signal over the U0/U1 band(s) in addition to the U2/U3 band(s). The CO may compute the channel response using a time average of the signal. From the averaged signal, the CO may calculate the slope of the response in the X43 tone set using a least squares fit method and the mean squared error of such a fit. The CO may then record both the slope and the mean squared error value. The slope (positive or negative), the intercept (an indirect indication of attenuation), and the mean squared error value may be used by the CO to determine whether the received signal is from a direct link or from a phantom link using the observations described above with respect to FIGS. 6-7. If a phantom link is detected, the CO may abstain from responding to the CPE with an ITU G.994.1 C-TONES signal, thereby aborting a potential phantom link. If the received signal is determined to be a direct-link signal then the CO may respond with the C-TONES signal to continue establishing the link. Phantom link detector 335 may obtain the frequency response, calculate the slope of the response, and then determine if the received signal is a phantom link signal.

An alternative technique in detecting phantom link signals to those already described is based on the correlation of signals at different ports of the CO, for example, CO1 and CO2. The correlation coefficient of the two signals is defined as:

$$ρ = \frac{\sum {s}_{1} ( t ) * {s}_{2} ( t )}{\sqrt{\sum {( {s}_{1} ( t ) )}^{2} \sum {( {s}_{2} ( t ) )}^{2}}}$$

where s₁ is the signal at CO1 and s₂ is the signal at CO2. If the signals are perfectly correlated (s₁ (t)=α s₂ (t)), then ρ=1. If there is no correlation, then ρ=0. In the example of scenario 600, ρ will be close to 1. In the example of scenario 650, ρ will be less than 1, the amount depending on the delay between the signals at CO1 and CO2. Based on ρ, the scenarios may be distinguished (for simplicity, just one tone, cos(ωt), is transmitted). In scenario 600, ρ=1. In scenario 650, where s₁ (t)=cos(ωt) and s₂ (t)=cos(ωt+θ), where θ=ωτ, τ being the delay between the two signals, then ρ=cos(θ).

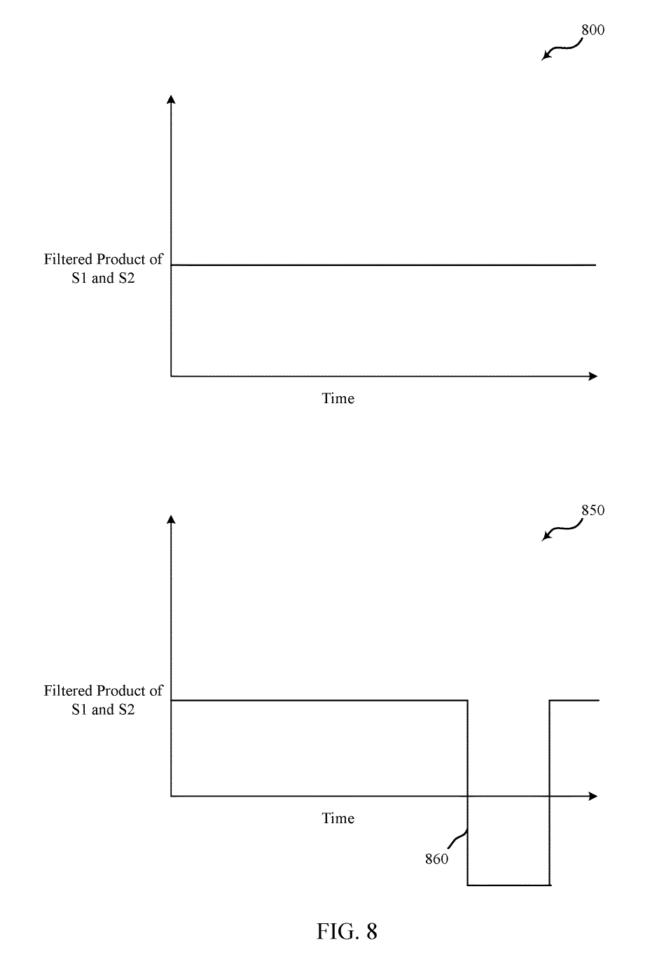

An additional technique may multiply the signals at CO1 and CO2 and then pass the result through a low pass filter. The output of the low pass filter using scenario 600 is depicted in timing diagram 800 of FIG. 8. The output of the low pass filter using scenario 650 is depicted in timing diagram 850. In timing diagram 850, 860 may represent the instance of a phase reversal.

Another technique for identifying a phantom data communication link may utilize a phase reversal detector (PRS) that detects symbols with a phase reversal. There are two types: a sidelobe energy based detector (SED) and a frequency domain synchronization algorithm (FDSA) based detector. The FDSA provides a position of phase reversal within an OFDM symbol. Based on this position, a PRS may be detected.

If SED is used in scenario 600, the distance between two phase reversal detections is a multiple of eight. In scenario 650, if the delay between both signals is more than an OFDM symbol, then the distance between two phase reversal detections need not be a multiple of eight. However, if in scenario 650 the delay between the signals is less than an OFDM symbol or a multiple of 8 OFDM symbols, the SED will detect it as scenario 600. In that case, the FDSA can be used to differentiate between the two scenarios. The FDSA can be extended to detect two phase reversals (one for direct-link and one for phantom links). If two phase reversals are detected then the likely scenario is scenario 600; otherwise it is likely scenario 650.

Another technique for identifying a phantom data communication link assumes a band of X tones is available for transmission during GHS. Each CPE may randomly select one tone to transmit during GHS. In scenario 600, both of the COs will see the presence of a tone from the band of X tones at the same location. In scenario 650, assuming the position of the tone from the band of X tones for each CPE is different, both COs will see two tones in the band of X tones (due to direct and phantom links).

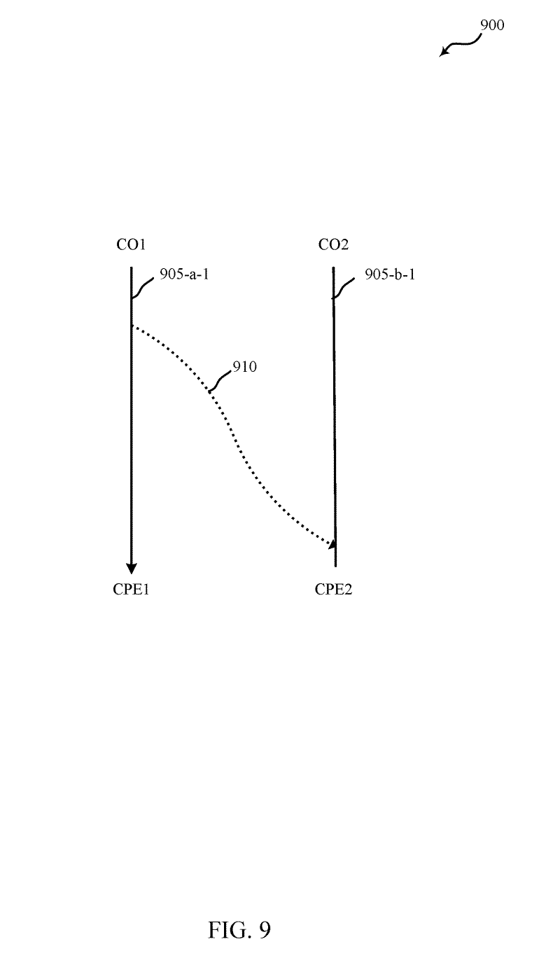

This technique may be extended to a downstream scenario as well. FIG. 9 depicts scenario 900 (direct links are depicted with solid lines and phantom links are depicted with dashed lines). The techniques can be performed by the COs 105, 205 and CPEs 110, 210 shown in FIGS. 1-2. In scenario 900, it is assumed that both CPEs have sent a signal to their respective COs for a connection. In the process, CO1 has sent tone TU1 in the band of X tones and CPE2 has sent a tone of TU2 in the band of X tones. CO1 detects DPE1 and responds while CO2 fails to detect CPE2. In scenario 900, CPE1 should lock and CPE2 should not lock as it is receiving phantom link 910. It is assumed that a CO responds with an additional tone TD=f(TU), which is a function of the tone received by it from its respective CPE. Since CPE2 sent a tone TU2, it expects a tone TD2=f(TU2). However, it sees a tone TD1≠f(TU2) and does not lock. CPE1, which sent a tone TU1 locks as it receives the expected tone TD1=f(TU1).

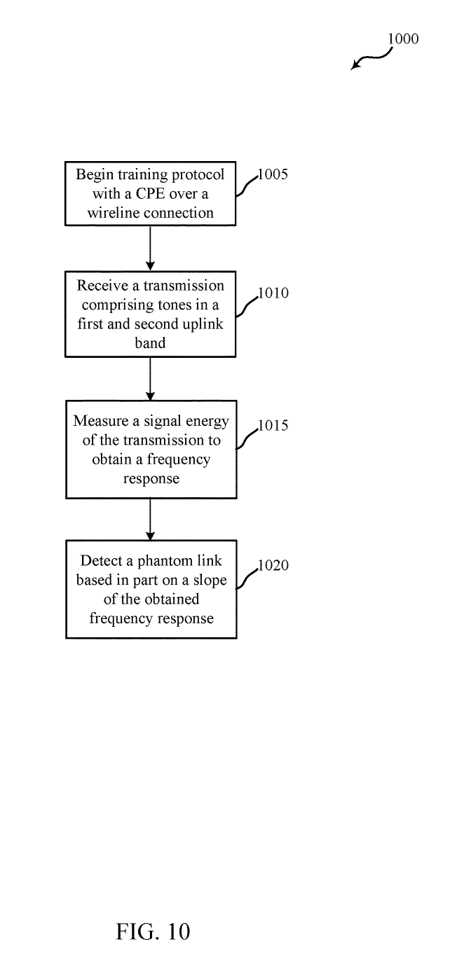

FIG. 10 is a flow chart illustrating an example of a method 1000 for phantom link detection, in accordance with various aspects of the present disclosure. For the purposes of illustration, the method 1000 will be described as it relates to the components of the CO apparatuses 305, 305-a shown in FIGS. 3A and 3B. This method 1000 can also be performed by the COs 105, 205 shown in FIGS. 1-2, which may be examples of the CO apparatuses 305, 305-a shown in FIGS. 3A and 3B. This method 1000 may be performed during handshaking (e.g., G.hs) procedures between DSL transceivers.

At block 1005, the DSL port controller 310 of the CO apparatus 305 begins a training protocol with a designated CPE over a line associated with a DSL port 315. At block 1010, as a part of the training protocol, CO apparatus 305 may receive a signal from the CPE via DSL port 315 which may be a signal over a first set of tones in a first uplink band and a second set of tones in a second uplink band outside of the first uplink band. The signal may be a request for a new DSL connection between the CO and the CPE.

At block 1015, the CO may measure a signal energy of the received request in order to calculate a frequency response for the request. This calculation may be performed over the U0/U1 band(s) in addition to the U2/U3 band(s). From this calculation, the CO may compute the channel response using a time average of the signal. This may be performed, for example, by phantom link detector 335.

At block 1020, the CO may detect a phantom link based in part on a slope of the calculated frequency response. The CO may calculate the slope of the response using a least squares fit method and the mean squared error of such a fit. The slope (positive or negative), the intercept (an indirect indication of attenuation), and the mean squared error value may be used by the CO to determine whether the received signal is from a direct link or from a phantom link using the observations described above with respect to FIGS. 6-7.

The detailed description set forth above in connection with the appended drawings describes examples and does not represent the only examples that may be implemented or that are within the scope of the claims. The terms “example” and “exemplary,” when used in this description, mean “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and apparatuses are shown in block diagram form in order to avoid obscuring the concepts of the described examples.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various illustrative blocks and components described in connection with the disclosure herein may be implemented or performed with a general-purpose processor, a digital signal processor (DSP), an ASIC, an FPGA or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope and spirit of the disclosure and appended claims. For example, due to the nature of software, functions described above can be implemented using software executed by a processor, hardware, firmware, hardwiring, or combinations of any of these. Features implementing functions may also be physically located at various positions, including being distributed such that portions of functions are implemented at different physical locations. As used herein, including in the claims, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination. Also, as used herein, including in the claims, “or” as used in a list of items (for example, a list of items prefaced by a phrase such as “at least one of” or “one or more of”) indicates a disjunctive list such that, for example, a list of “at least one of A, B, or C” means A or B or C or AB or AC or BC or ABC (i.e., A and B and C).

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a web site, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The previous description of the disclosure is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not to be limited to the examples and designs described herein but is to be accorded the broadest scope consistent with the principles and novel features disclosed herein.

What is claimed is:

1. A method for identifying phantom data communication links, comprising:
receiving, by a central office (CO) device, a transmission from a customer premises equipment (CPE) device comprising a request for a new DSL connection over a first set of tones in a first uplink band and a second set of tones in a second uplink band outside of the first uplink band;
measuring, by the CO device, a signal energy of the received request to obtain a frequency response of the received request over the first uplink band and the second uplink band; and
detecting a phantom data communication link based at least in part on a slope of the frequency response of the received request over the first uplink band and the second uplink band.

2. The method of claim 1, further comprising:
determining a time average of the transmission from the CPE device; and
determining the slope of the frequency response based at least in part on the time average;
wherein the phantom data communication link is detected based at least in part on a difference between the slope of the frequency response and a threshold.

3. The method of claim 2, wherein determining the slope of the frequency response utilizes a least squares fit method.

4. The method of claim 1, wherein detecting the phantom data communication link comprises:
comparing the measured signal energy against a predetermined threshold.

5. The method of claim 1, wherein the first uplink band comprises at least one of: an ITU U0 band or an ITU U1 band.

6. The method of claim 1, wherein the first set of tones comprises at least one of: an ITU G.994 A43 tone set or an ITU G.994 V43 tone set.

7. The method of claim 1, wherein the received request is a modified R_TONES_REQ signal, the modified R_TONES_REQ signal comprising a plurality of tones spaced evenly over the second uplink band.

8. The method of claim 7, wherein the second uplink band comprises at least one of: an ITU U2 band or an ITU U3 band.

9. The method of claim 1, wherein a downlink band is between the first uplink band and the second uplink band.

10. An apparatus for identifying phantom data links, comprising:
means for receiving, by a central office (CO) device, a transmission from a customer premises equipment (CPE) device comprising a request for a new DSL connection over a first set of tones in a first uplink band and a second set of tones in a second uplink band outside of the first uplink band;
means for measuring, by the CO device, a signal energy of the received request to obtain a frequency response of the received request over the first uplink band and the second uplink band; and
means for detecting a phantom data communication link based at least in part on a slope of the frequency response of the received request over the first uplink band and the second uplink band.

11. The apparatus of claim 10, further comprising:
means for determining a time average of the transmission from the CPE device; and
means for determining the slope of the frequency response based at least in part on the time average;
wherein the phantom data communication link is detected based at least in part on a difference between the slope of the frequency response and a threshold.

12. The apparatus of claim 11, wherein determining the slope of the frequency response utilizes a least squares fit method.

13. The apparatus of claim 10, wherein the means for detecting the phantom data communication link comprises:
means for comparing the measured signal energy against a predetermined threshold.

14. The apparatus of claim 10, wherein the first uplink band comprises at least one of: an ITU U0 band or an ITU U1 band.

15. The apparatus of claim 10, wherein the first set of tones comprises at least one of: an ITU G.994 A43 tone set or an ITU G.994 V43 tone set.

16. The apparatus of claim 10, wherein the received request is a modified R_TONES_REQ signal, the modified R_TONES_REQ signal comprising a plurality of tones spaced evenly over the second uplink band.

17. The apparatus of claim 16, wherein the second uplink band comprises at least one of: an ITU U2 band or an ITU U3 band.

18. The apparatus of claim 10, wherein a downlink band is between the first uplink band and the second uplink band.

19. An apparatus for identifying phantom data links, comprising:
a processor;
memory in electronic communication with the processor; and
instructions stored in the memory and operable, when executed by the processor, to cause the apparatus to:
receive, by a central office (CO) device, a transmission from a customer premises equipment (CPE) device comprising a request for a new DSL connection over a first set of tones in a first uplink band and a second set of tones in a second uplink band outside of the first uplink band;
measure, by the CO device, a signal energy of the received request to obtain a frequency response of the received request over the first uplink band and the second uplink band; and
detect a phantom data communication link based at least in part on a slope of the frequency response of the received request over the first uplink band and the second uplink band.

20. The apparatus of claim 19, the instructions to further cause the apparatus to:
determine a time average of the transmission from the CPE device; and
determine the slope of the frequency response based at least in part on the time average;
wherein the phantom data communication link is detected based at least in part on a difference between the slope of the frequency response and a threshold.

21. The apparatus of claim 20, wherein determining the slope of the frequency response utilizes a least squares fit method.

22. The apparatus of claim 19, wherein the instructions operable to cause the apparatus to detect the phantom data communication link comprise instructions operable to cause the apparatus to:
compare the measured signal energy against a predetermined threshold.

23. The apparatus of claim 19, wherein the first uplink band comprises at least one of: an ITU U0 band or an ITU U1 band.

24. The apparatus of claim 19, wherein the first set of tones comprises at least one of: an ITU G.994 A43 tone set or an ITU G.994 V43 tone set.

25. The apparatus of claim 19, wherein the received request is a modified R_TONES_REQ signal, the modified R_TONES_REQ signal comprising a plurality of tones spaced evenly over the second uplink band.

26. The apparatus of claim 25, wherein the second uplink band comprises at least one of: an ITU U2 band or an ITU U3 band.

27. The apparatus of claim 19, wherein a downlink band is between the first uplink band and the second uplink band.

28. A non-transitory computer-readable medium storing code for identifying phantom data communication links, the code comprising instructions executable to:
receive, by a central office (CO) device, a transmission from a customer premises equipment (CPE) device comprising a request for a new DSL connection over a first set of tones in a first uplink band and a second set of tones in a second uplink band outside of the first uplink band;
measure, by the CO device, a signal energy of the received request to obtain a frequency response of the received request over the first uplink band and the second uplink band; and
detect a phantom data communication link based at least in part on a slope of the frequency response of the received request over the first uplink band and the second uplink band.

29. The non-transitory computer-readable medium of claim 28, the instructions further executable to:
determine a time average of the transmission from the CPE device; and
determine the slope of the frequency response based at least in part on the time average;
wherein the phantom data communication link is detected based at least in part on a difference between the slope of the frequency response and a threshold.

30. The non-transitory computer-readable medium of claim 29, wherein determining the slope of the frequency response utilizes a least squares fit method.
